(19) United States
(12) Patent Application Publication
(10) Pub. No.: US 2026/0040626 A1
(43) Pub. Date: Feb. 5, 2026

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: PO-HSIEN CHENG, HSINCHU CITY (TW); I-HSUAN LO, HSINCHU CITY (TW); KENG-CHU LIN, PING-TUNG (TW); PINYEN LIN, ROCHESTER, NY (US); TAI-CHUN HUANG, HSIN-CHU CITY (TW); CHI ON CHUI, HSINCHU CITY (TW)

(21) Appl. No.: 18/792,605

(22) Filed: Aug. 2, 2024

(51) Int. Cl. H01L 29/49; H01L 21/28; H01L 29/06; H01L 29/423; H01L 29/66; H01L 29/775; H01L 29/786; H10B 10/00

(52) U.S. Cl. CPC H10D 30/6739; H01L 21/28123; H10D 30/014; H10D 30/43; H10D 30/6735; H10D 30/6757; H10D 62/121; H10D 64/017; H10B 10/125

(57) ABSTRACT

A semiconductor device and method of manufacturing the same are provided. The semiconductor device includes a substrate, a first set of nanostructures and a second set of nanostructures on the substrate, a first gate electrode wrapping the first set of nanostructures and the second set of nanostructures, and a gate-cut structure between the first set of nanostructures and the second set of nanostructures. The gate-cut structure includes a barrier layer adjacent to the first gate electrode and a dielectric layer spaced apart from the first gate electrode by the barrier layer.

### BACKGROUND

The semiconductor integrated circuit (IC) industry has experienced rapid growth. Technological advances in IC materials and design have produced generations of ICs, each with smaller and more complex circuits than the previous generation. However, these advances have increased the complexity of processing and manufacturing ICs. For these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling-down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a perspective view of a semiconductor device in accordance with some embodiments.

FIG. 2A is a cross-sectional view of the semiconductor device along line A-A′ of FIG. 1 in accordance with some embodiments.

FIG. 2B is a cross-sectional view of the semiconductor device along line B-B′ of FIG. 1 in accordance with some embodiments.

FIG. 3, FIG. 4A to FIG. 16A, and FIG. 4B to FIG. 16B illustrate various stages of manufacturing a semiconductor device, in accordance with some embodiments of the present disclosure.

FIG. 17 is a flowchart of a method for manufacturing a semiconductor device according to various aspects of the present disclosure.

FIG. 18 is a schematic of an SRAM circuit cell according to various aspects of the present disclosure.

FIG. 19 is a partial layout of an SRAM circuit cell according to various aspects of the present disclosure.

FIG. 20 is a cross-sectional view of a semiconductor device in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

With advances in semiconductor technology, multi-gate devices have been introduced to improve gate control by increasing gate-channel coupling, reducing off-state current, and reducing short-channel effects (SCEs). One such multi-gate device is the nanostructure transistor, which includes the gate-all-around field effect transistor (GAA FET), the nanosheet transistor, the nanowire transistor, the multi bridge channel transistor, the nano-ribbon transistor, and other similar structured transistors. The nanostructure transistor provides a channel in a stacked nanosheet/nanowire configuration. The GAA FET device derives its name from the gate structure that can extend around the channel and provide gate control of the channel on multiple sides of the channel. Nanostructure transistor devices are compatible with MOSFET manufacturing processes and their structure allows them to be scaled while maintaining gate control and mitigating SCEs.

Gate structures in nanostructure transistors can extend over two or more of the nanostructure transistors. For example, the gate structures can extend across multiple active regions (e.g., fin regions) of the nanostructure transistors. Once the gate structures are formed, a patterning process can “cut” one or more of the gate structures into shorter sections according to the desired structure. In other words, the patterning process can remove gate portions of the one or more gate structures to form one or more isolation trenches (also referred to as “metal cuts”) between the nanostructure transistors and separate the gate structures into shorter sections. This process is referred to as a cut-metal-gate (CMG) process. Subsequently, the isolation trenches formed between the separated sections of the gate structures can be filled with a dielectric material to form gate-cut structures, which can electrically isolate the separated gate structure sections. In some cases, said dielectric material generates positive fixed charges adjacent to an interface between the dielectric material and a substrate (e.g., silicon substrate), which induces threshold voltage (Vth) shift and body leakage issues, especially in static random-access memory (SRAMs) devices.

Various embodiments in the present disclosure provide semiconductor devices including a gate-cut structure for cutting gate portions in a semiconductor device having nanostructure transistors (e.g., a GAA FETs) and/or other semiconductor devices in an integrated circuit (IC).

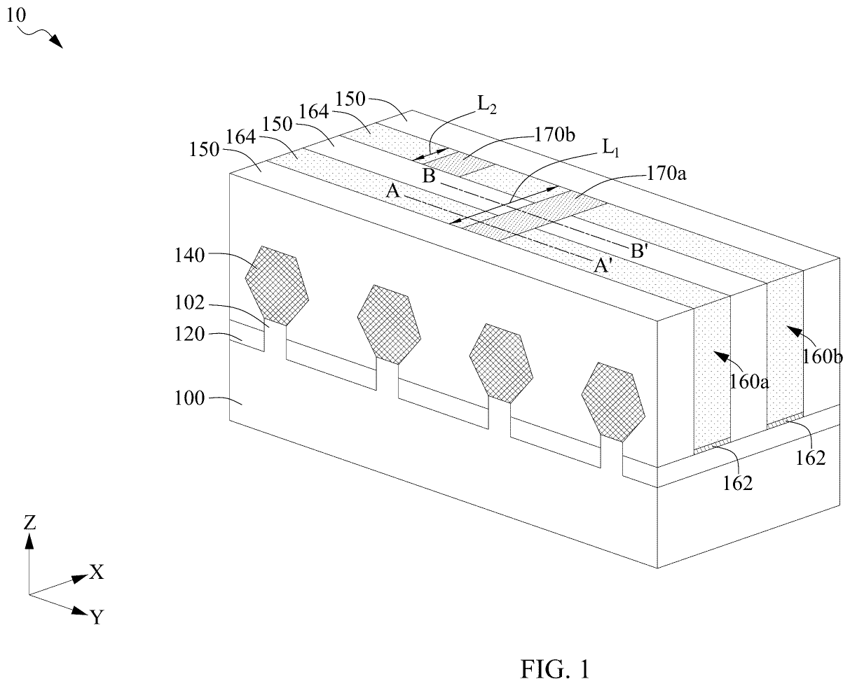

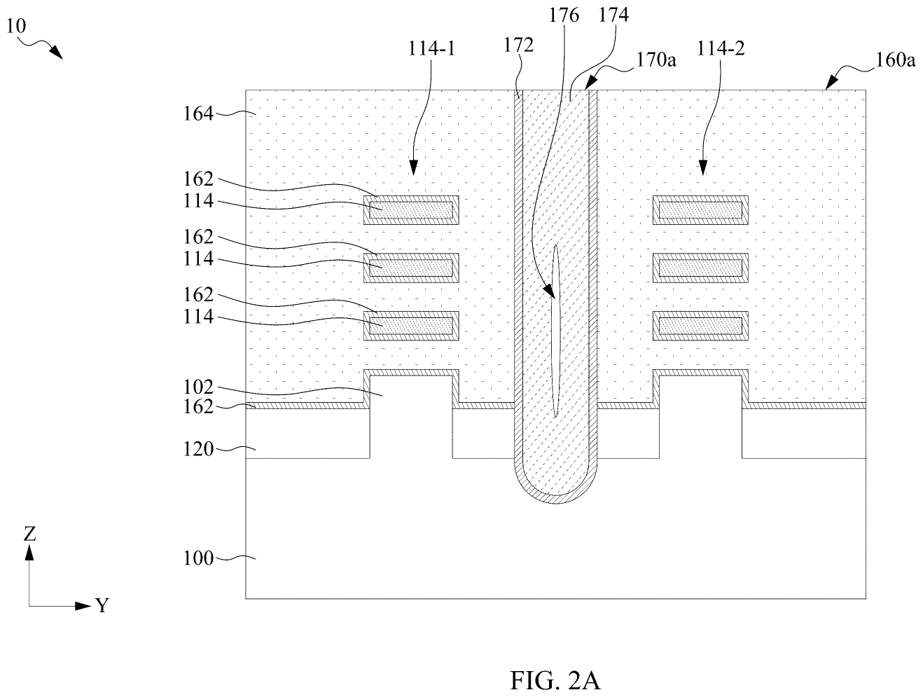

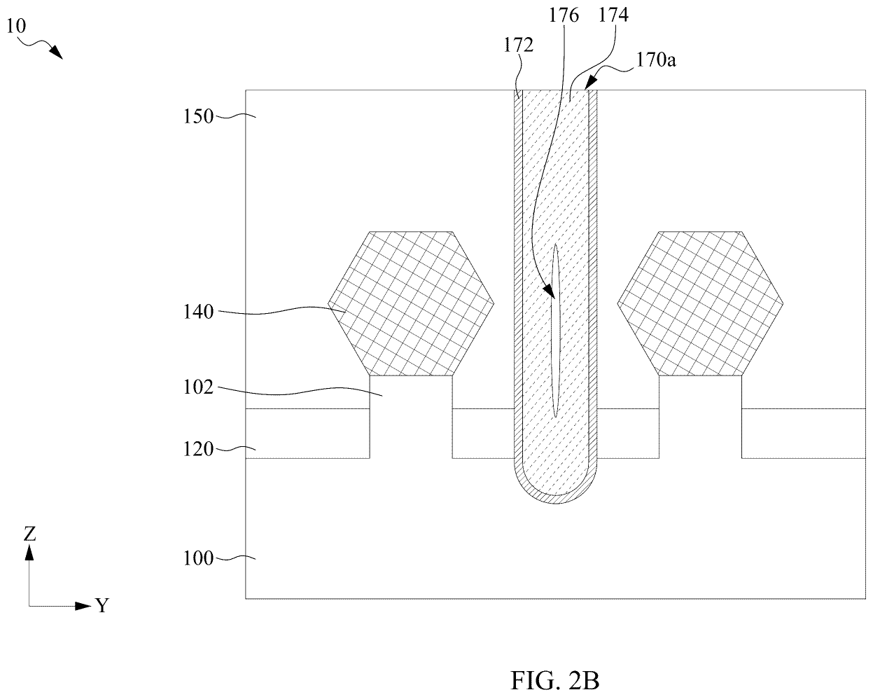

FIGS. 1, 2A and 2B illustrate a semiconductor device 10 in accordance with some embodiments, wherein FIG. 1 is a perspective view, FIG. 2A is a cross-sectional view taken along line A-A′, and FIG. 2B is a cross-sectional view taken along line B-B′ of FIG. 1. In some embodiments, the semiconductor device 10 includes a substrate 100, an isolation layer 120, source/drain (S/D) structures 140, an interlayer dielectric (ILD) 150, gate structures 160a and 160b, as well as gate-cut structures 170a and 170b.

The substrate 100 may be a semiconductor substrate, such as a bulk semiconductor, a semiconductor-on-insulator (SOI) substrate, or the like, which may be doped (e.g., with a p-type or an n-type impurity) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, which may be a silicon or glass substrate. Other substrates, such as a multi-layered or gradient substrate may also be used. In some embodiments, the substrate 100 may be a material, such as a III-V compound semiconductor, a II-VI compound semiconductor, or the like. In some embodiments, the semiconductor material of the substrate 100 may include silicon; germanium; a compound semiconductor including silicon carbide, gallium arsenide, gallium stannum, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The substrate 100 has an n-type region and a p-type region. The n-type region can be for forming n-type devices, such as NMOS transistors, e.g., n-type nano-FETs, and the p-type region can be for forming p-type devices, such as PMOS transistors, e.g., p-type nano-FETs. In some embodiments, the substrate 100 includes well regions 101a and 101b. The well region 101a has a conductive type different from that of the well region 101b. For example, the well region 101a is a p-type region, and the well region 101b is an n-type region.

The semiconductor device 10 includes fins 102. Each of the fins 102 protrudes from the substrate 100. Each of the fins 102 extends along the X direction. Each of the fins 102 is a semiconductor strip patterned in the substrate 100. The fins 102 define a plurality of trenches (not annotated).

The isolation layer 120 is disposed within the trenches defined by the fins 102. The isolation layers 120 are recessed from an upper surface (not annotated) of the fins 102. In some embodiments, the isolation layer 120 may be shallow trench isolation (STI) structures, deep trench isolation (DTI) structures, or the like.

The S/D structures 140 are disposed over the substrate 100 and on opposite sides of the gate structure 160a (or gate structure 160b). The S/D structures 140 can function as S/D regions of a transistor(s). In some embodiments, the S/D structures 140 can have any geometric shape, such as a polygon, an ellipsis, and a circle. In some embodiments, the S/D structures 140 can include an epitaxially-grown semiconductor material, such as silicon (e.g., the same material as the substrate 100). In some embodiments, the epitaxially-grown semiconductor material can include an epitaxially-grown semiconductor material different from the material of the substrate 100, such as silicon germanium, and imposes strain on the channel regions under the gate structure 160a (or gate structure 160b). Since the lattice constant of such epitaxially-grown semiconductor material is different from the material of the substrate 100, the channel regions are strained to increase carrier mobility in the channel regions of semiconductor device 10. The epitaxially-grown semiconductor material includes a semiconductor material (e.g., germanium and silicon), a compound semiconductor material (e.g., gallium arsenide and aluminum gallium arsenide), a semiconductor alloy (e.g., silicon germanium and gallium arsenide phosphide) or other suitable materials.

In some embodiments, the S/D structures 140 can include silicon and can be in-situ doped during an epitaxial growth process using n-type dopants, such as phosphorus and arsenic. In some embodiments, the S/D structures 140 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, the S/D structures 140 can include one or more epitaxial layers, where each epitaxial layer can have different compositions. Although FIGS. 1, 2A, and 2B illustrate that one S/D structure 140 is formed on one fins 102, the embodiments of the present disclosure are not limited thereto. In other embodiments, one S/D structure 140 can be formed on two or more fins 102 depending on requirements. In other embodiments, a portion of the fins 102 may be etched so that the upper surfaces of the fins are below the upper surface of the isolation layer 120, and the S/D structures 140 grow from the recessed upper surfaces of the fins. In this condition, portions of the S/D structures 140 are embedded within the isolation layer.

In some embodiments, an S/D contact structure (not shown) is disposed on the S/D structures 140. The S/D contact structure is configured to connect S/D structures 140 to other elements of semiconductor device 10 and/or of the integrated circuit. The S/D contact structure can include metal silicide layers and conductive regions disposed on metal silicide layers (not shown). In some embodiments, an etch stop layer (not shown) is conformally disposed on the S/D structures 140. The etch stop layer includes silicon nitride, silicon oxide, silicon oxynitride, or other suitable materials.

The ILD 150 is disposed on the S/D structures 140 and the isolation layer 120. The ILD 150 includes a dielectric material deposited using a deposition method suitable for flowable dielectric materials. The ILD 150 defines trenches for accommodating gate structures (e.g., the gate structures 160a and 160b). The ILD 150 includes an oxide, such as phospho-silicate glass (PSG), boro-silicate glass (BSG), boron-doped phospho-silicate glass (BPSG), tetra ethyl ortho silicate (TEOS) oxide, or other suitable materials.

In some embodiments, the semiconductor device includes semiconductor sheets 114 (see FIG. 2A). Each of the semiconductor sheets 114 extends along the X direction. The semiconductor sheets 114 can include a first set of nanostructures 114-1 and a second set of nanostructures 114-2, which can be in the form of nanosheets, nanowires, or nano-ribbons stacked along the Z direction. Each of the semiconductor sheets 114 can form a channel region of a transistor. In some embodiments, the semiconductor sheets 114 include semiconductor materials similar to or different from the substrate 100. In some embodiments, the semiconductor sheets 114 include silicon, silicon germanium, or other suitable materials. The semiconductor materials of the semiconductor sheets 114 can be undoped or can be in-situ doped during their epitaxial growth process.

Each of the gate structures 160a and 160b are disposed on the substrate 100. Each of the gate structures 160a and 160b extends along the Y direction. The gate structures 160a and 160b are disposed within the trenches of the ILD 150. In some embodiments, each of the gate structures 160a and 160b includes a gate dielectric layer 162 and a gate electrode layer 164. As shown in FIGS. 2A and 2B, the gate dielectric layer 162 and the gate electrode layer 164 can wrap around the semiconductor sheets 114.

The gate dielectric layer 162 is disposed between the semiconductor sheets 114 and the gate electrode layer 164. In some embodiments, the gate dielectric layer 162 can include silicon oxide or a high-k dielectric layer in direct contact with the semiconductor sheets 114. The term “high-k” can refer to a high dielectric constant. In the field of semiconductor device structures and manufacturing processes, high-k can refer to a dielectric constant that is greater than the dielectric constant of silicon oxide (e.g., greater than about 3.9). In some embodiments, the gate dielectric layer 162 includes metal oxide or a silicate of hafnium, aluminum, zirconium, lanthanum, manganese, barium, titanium, lead, and combinations thereof.

In some embodiments, the gate electrode layer 164 includes a work function metal layer(s) conformally disposed on the gate dielectric layer 162 and a metal fill on the work function metal layer(s). In some embodiments, an n-type work function metal layer can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, a p-type work function metal layer can include titanium nitride, titanium silicon nitride, tantalum nitride, tungsten carbon nitride, tungsten, molybdenum, or other suitable work function metals. In some embodiments, the work function metal layer can include a single metal layer or a stack of metal layers. The stack of metal layers can include work function metals having work-function values equal to or different from each other. The metal fill can include titanium, tantalum, aluminum, cobalt, tungsten, nickel, ruthenium, or other suitable conductive materials.

Each of the gate-cut structures 170a and 170b is disposed on the substrate 100. In some embodiments, each of the gate-cut structures 170a and 170b is configured to cut a gate structure(s), such as the gate structure 160a and/or 160b. In some embodiments, each of the gate-cut structures 170a and 170b penetrates a gate structure(s) (e.g., the gate structure 160a and/or 160b). In some embodiments, each of the gate-cut structures 170a and 170b penetrates the isolation layer 120 and is in contact with the substrate 100. In some embodiments, each of the gate-cut structures 170a and 170b includes a leakage barrier layer 172 (or barrier layer), a dielectric layer 174 (or an isolation layer), and an air gap 176 as shown in FIGS. 2A and 2B.

In some embodiments, the leakage barrier layer 172 is configured to separate the dielectric layer 174 and the gate electrode layer 164. In some embodiments, the leakage barrier layer 172 is in contact with the gate electrode layer 164. The leakage barrier layer 172 is spaced apart from the gate dielectric layer 162. In some embodiments, the leakage barrier layer 172 is disposed between the first set of nanostructures 114-1 and second set of nanostructures 114-2. In some embodiments, the leakage barrier layer 172 penetrates the isolation layer 120. In some embodiments, the leakage barrier layer 172 is in contact with the substrate 100. In some embodiments, the leakage barrier layer 172 is conformally disposed on the sidewall of the gate electrode layer 164, the sidewall of the isolation layer 120, and/or the upper surface of the substrate 100. In some embodiments, the leakage barrier layer 172 includes a curved lower surface protruding toward the substrate 100. In some embodiments, the leakage barrier layer 172 includes negative fixed charge materials, which are prone to generating negative fixed charge(s). In some embodiments, the leakage barrier layer 172 is configured to generate negative fixed charge(s) adjacent to an interface between the leakage barrier layer 172 and the substrate 100, which can build an electric field that repels carriers from the body region of a transistor, reducing the leakage current.

In some embodiments, the leakage barrier layer 172 includes metal oxide, metal nitride, metal oxynitride, or a combination thereof. In some embodiments, the leakage barrier layer 172 includes aluminum oxide (Al₂O₃), aluminum oxynitride (AlON), aluminum nitride (AlN), hafnium dioxide (HfO₂), hafnium oxynitride (HfON), hafnium nitride (HfN), zirconium dioxide (ZrO₂), zirconium oxynitride (ZrON), zirconium nitride (ZrN), titanium dioxide (TiO₂), titanium oxynitride (TION), titanium nitride (TiN), gadolinium oxide (Gd₂O₃), gadolinium oxynitride (GdON), gadolinium nitride (GdN), lanthanum oxide (La₂O₃), lanthanum oxynitride (LaON), lanthanum nitride (LaN), yttrium oxide (Y₂O₃), yttrium oxynitride (YON), yttrium nitride (YN), lutetium oxide (Lu₂O₃), lutetium oxynitride (LuON), lutetium nitride (LuN), scandium oxide (Sc₂O₃), scandium oxynitride (ScON), scandium nitride (ScN), dysprosium oxide (Dy₂O₃), dysprosium oxynitride (DyON), dysprosium nitride (DyN), or other suitable materials.

The dielectric layer 174 fills the trench (or opening) defined by the gate structure 160a (or gate structure 160b). In some embodiments, the dielectric layer 174 is spaced apart from the gate structure 160 by the leakage barrier layer 172. The dielectric layer 174 penetrates the gate structure 160a (or gate structure 160b). In some embodiments, an upper surface of the dielectric layer 174 is substantially aligned with an upper surface of the leakage barrier layer 172. In some embodiments, the dielectric layer 174 may extend into and be surrounded by the substrate 100. In some embodiments, the dielectric layer 174 includes a low-k dielectric material, such as silicon oxide, silicon oxynitride, or other suitable materials. In some embodiments, the leakage barrier layer 172 has a dielectric constant greater than that of the dielectric layer 174. In some embodiments, the leakage barrier layer 172 has a dielectric constant similar to or greater than that of silicon nitride. In some cases, during formation of the dielectric layer 174, the leakage barrier layer 172 may prevent oxidation of the gate structure 160a (or gate structure 160b), which thereby enhances the yield of the manufacturing. In some embodiments, the leakage barrier layer 172 may include aluminum oxide or other suitable materials, and the dielectric layer 174 may include silicon oxide or other suitable materials.

In some embodiments, the air gap 176 is surrounded by the dielectric layer 174. The dielectric layer 174 can reduce the parasitic capacitance, which thereby improves the performance of the semiconductor device 10.

As shown in FIG. 1, the gate-cut structure 170a has a length L₁ along the X direction. The gate-cut structure 170b has a length L₂ along the X direction. In some embodiments, the length L₁ is different from the length L₂. In some embodiments, the gate-cut structure 170a further extends between the gate structures 160a and 160b. The gate-cut structure 170a can further be disposed between abutting S/D structures 140 as shown in FIG. 2B. In some embodiments, the lengths of the gate-cut structures 170a and 170b can depend on the layout of the semiconductor device 10.

In a comparative embodiment, positive fixed charge material (e.g., silicon nitride) is configured to serve as an isolation structure or a leakage barrier layer. In this case, the positive fixed charge material creates an electric field that attracts carriers from the body region of a transistor towards the positive fixed charge material, causing a leakage current. In the embodiments of this disclosure, a negative fixed charge material and an isolation layer are used to function as a gate-cut structure. Metal-oxygen bonds and/or metal-nitride bonds contain oxygen or nitrogen vacancies or interstitials, which introduce excess electrons into the material. As a result, excess electrons act as negative charges and create a negative fixed charge in the leakage barrier layer 172. These negative charges can be used to attract positive charges from the substrate 100, effectively creating a potential barrier that prevents current flow. The isolation layer can define an air gap and has a relatively low dielectric constant, which reduces the parasitic capacitance. This can help to improve device performance and reduce power consumption.

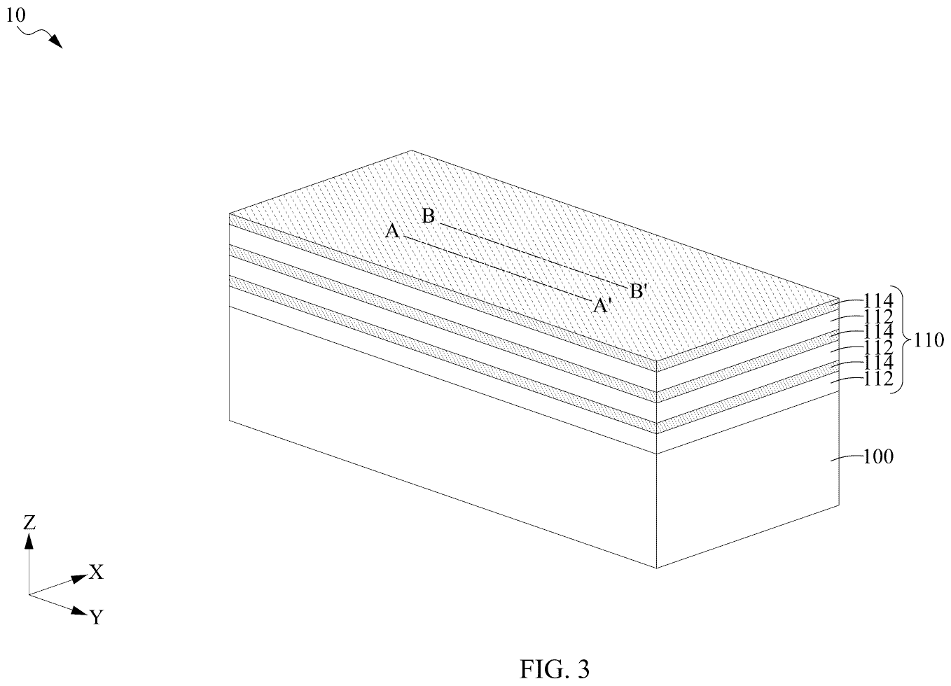

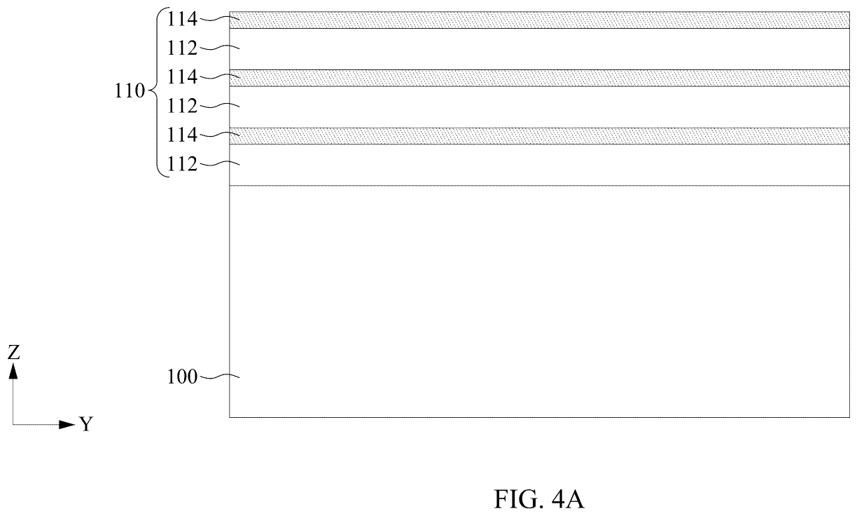

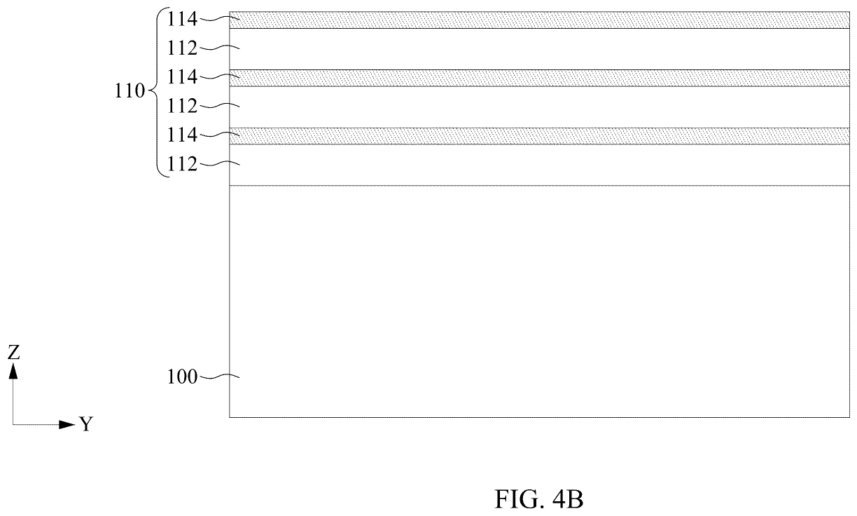

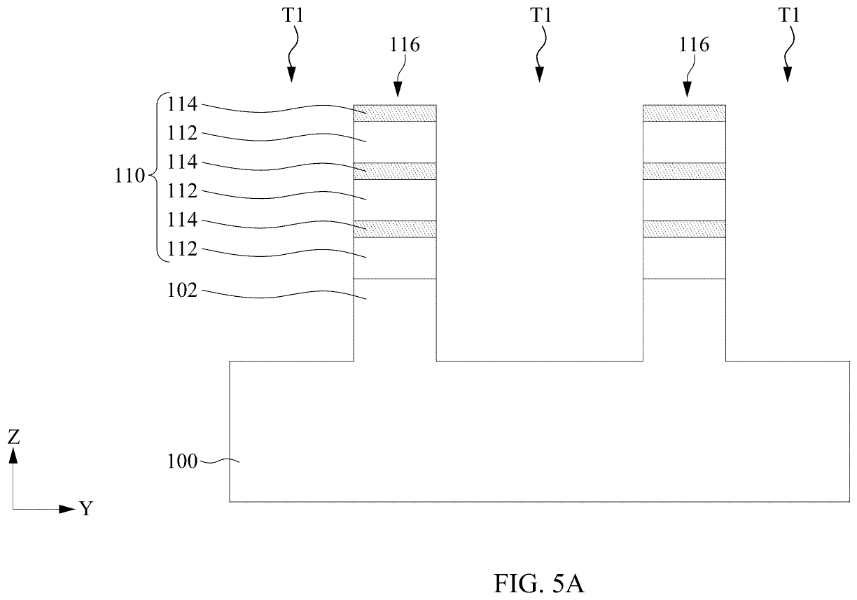

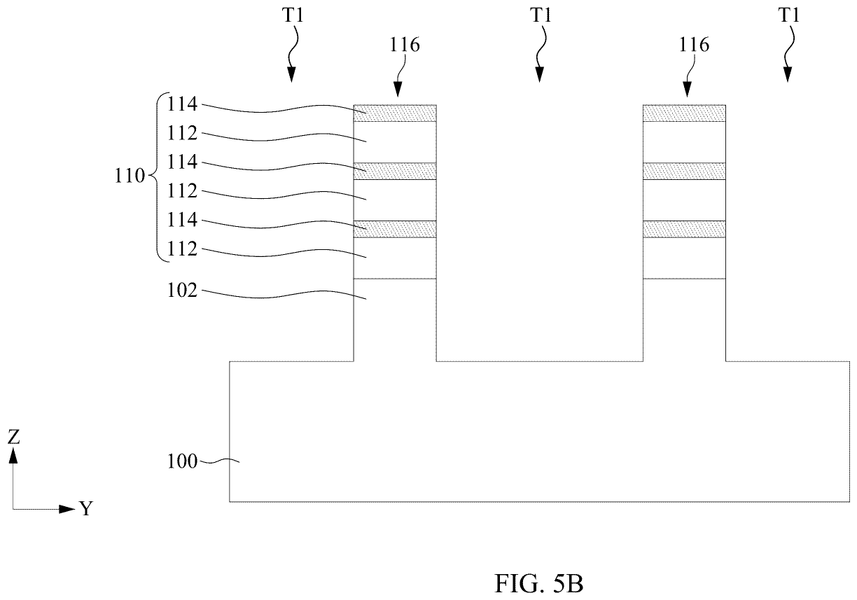

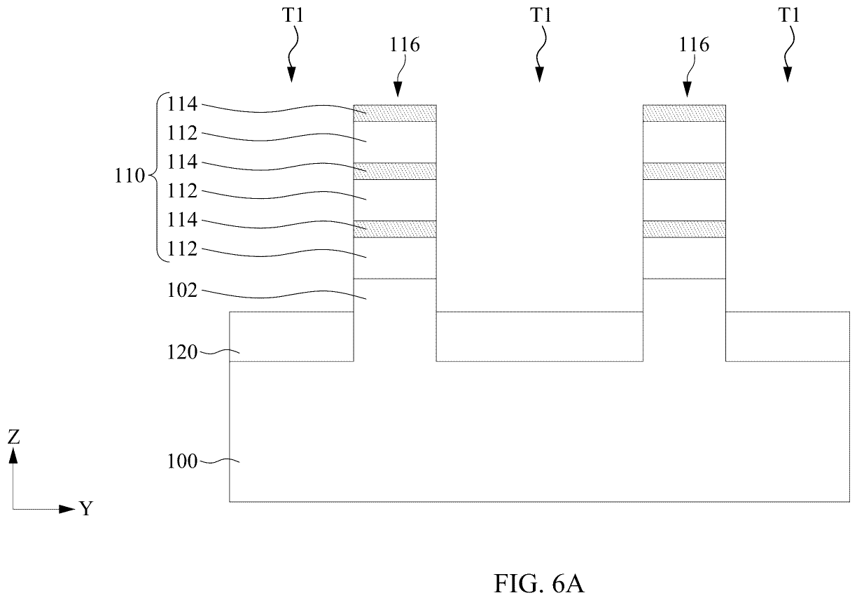

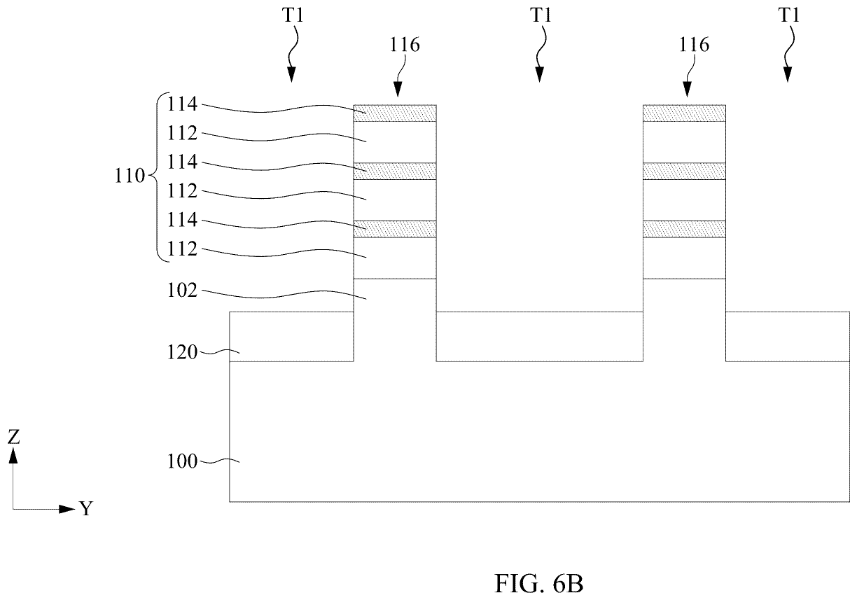

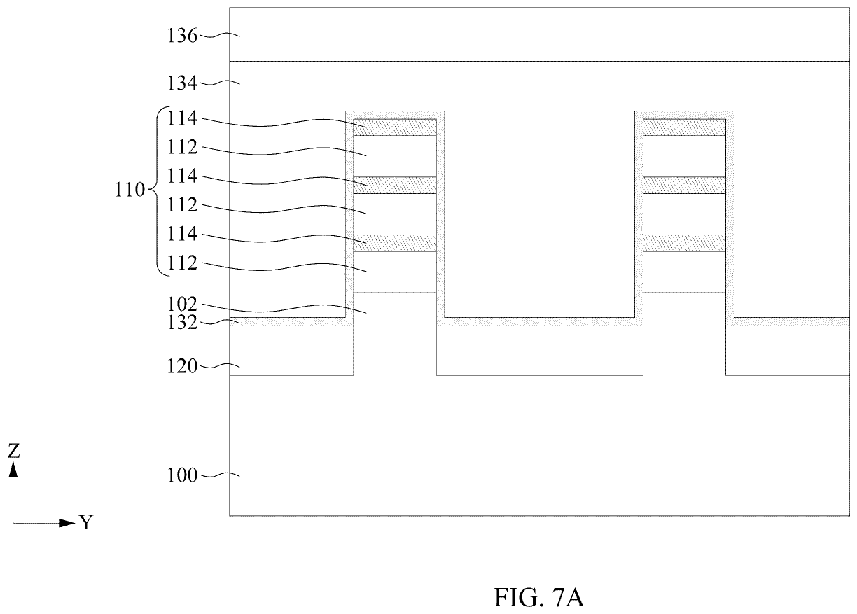

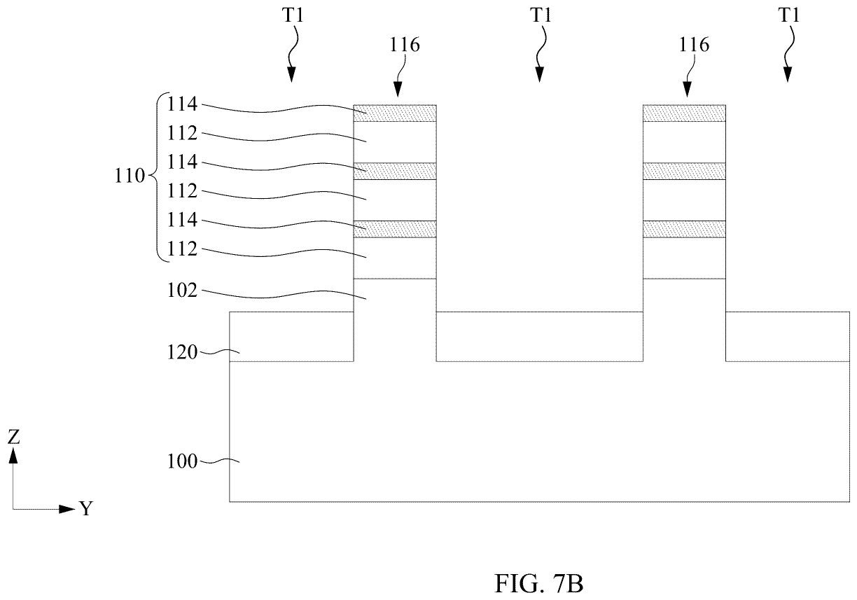

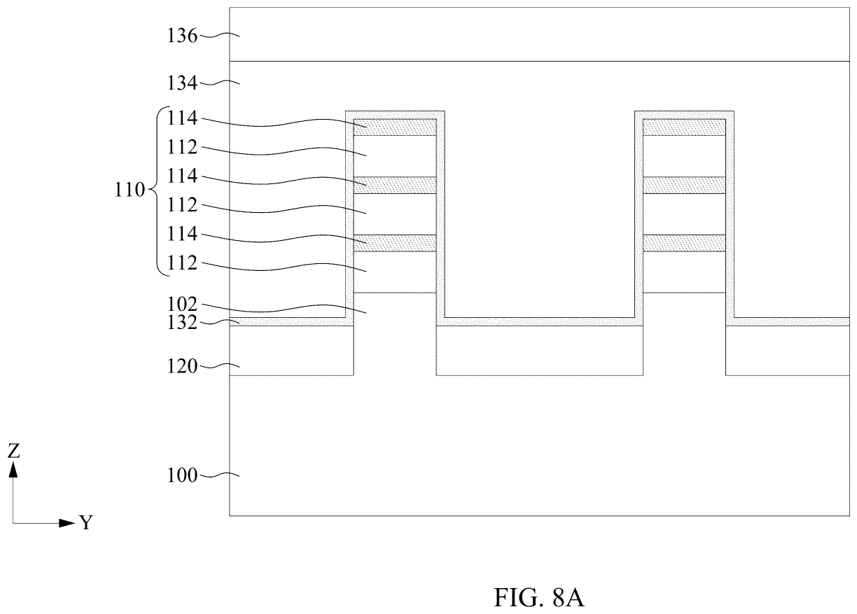

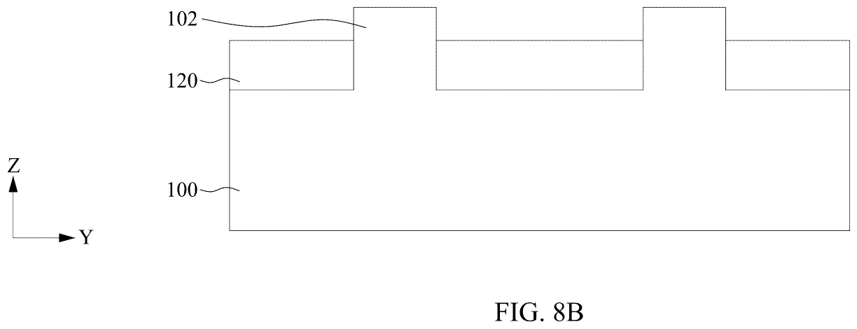

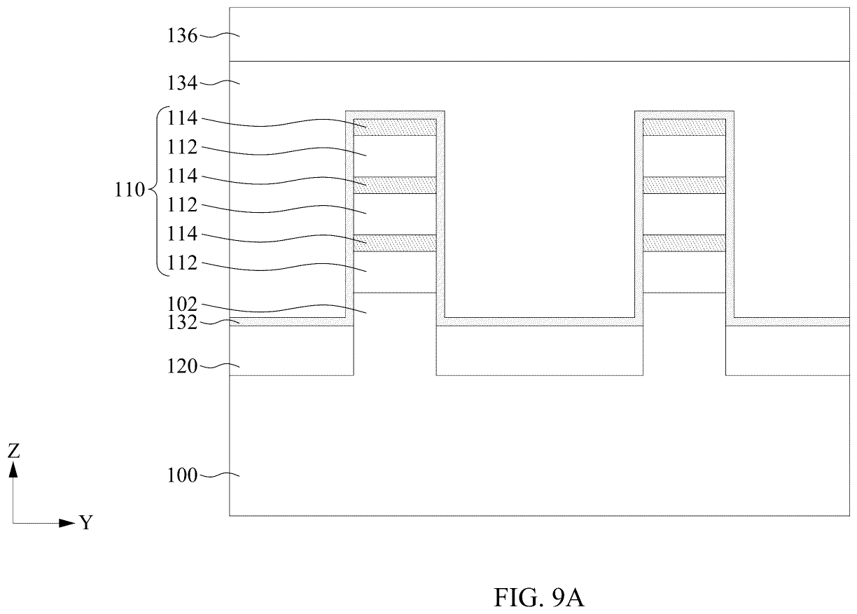

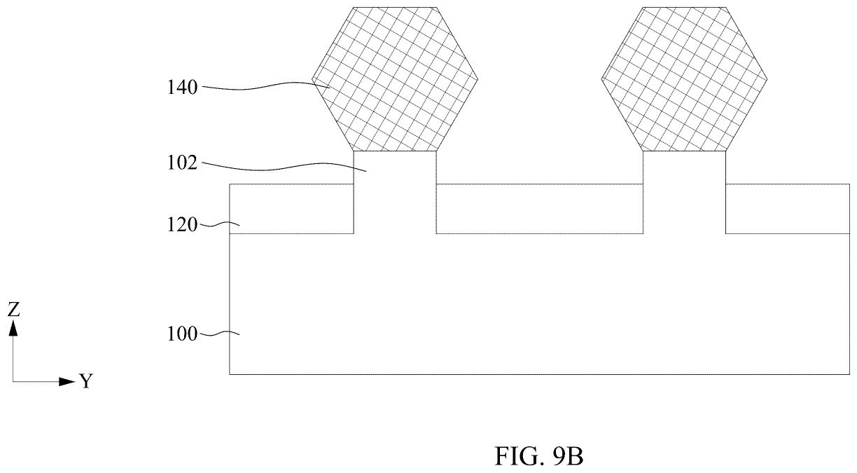

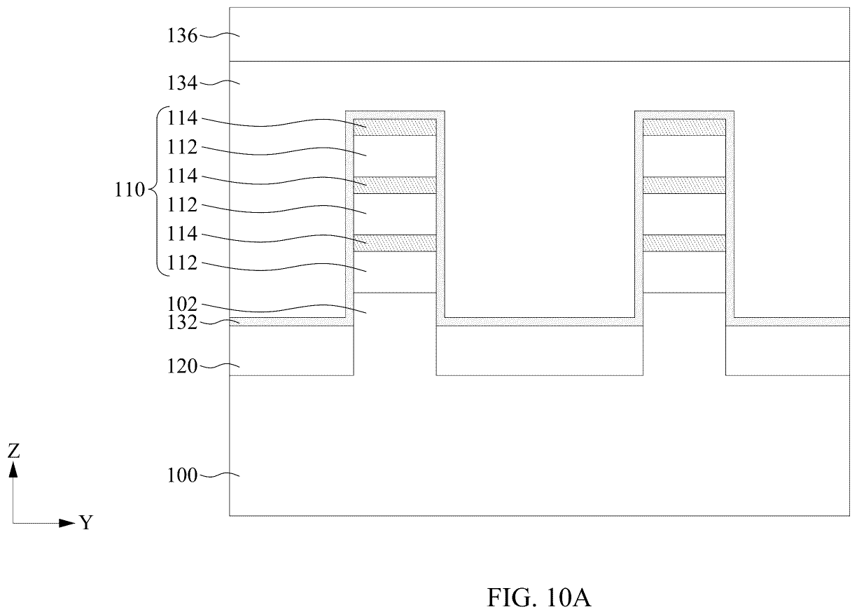

FIG. 3, FIG. 4A to FIG. 16A, and FIG. 4B to FIG. 16B illustrate various stages of manufacturing a semiconductor device, in accordance with some embodiments of the present disclosure. FIG. 3 is a perspective view, and FIGS. 4A and 4B are cross-sectional views along lines A-A′ and B-B′ of FIG. 3, respectively. FIGS. 5A to 16A and FIGS. 5B to 16B illustrate various stages followed by the stage as shown in FIGS. 4A and 4B, respectively.

Referring to FIGS. 3, 4A, and 4B, the substrate 100 is provided. A multi-layer stack 110 is formed over the substrate 100. The multi-layer stack 110 includes alternating semiconductor sheets 112 and semiconductor sheets 114. The semiconductor sheets 112 are formed of a first semiconductor material, and the semiconductor sheets 114 are formed of a second semiconductor material. The semiconductor materials may each be selected from the candidate semiconductor materials of the substrate 100. In some embodiments, the multi-layer stack 110 includes three layers of each of the semiconductor sheets 112 and the semiconductor sheets 114. It should be appreciated that the multi-layer stack 110 may include any number of the semiconductor sheets 112 and the semiconductor sheets 114.

In some embodiments, the semiconductor sheets 112 will be removed and the semiconductor sheets 114 will patterned to form channel layers for the nano-FETs. The semiconductor sheets 112 are sacrificial layers (or dummy layers), which will be removed in subsequent processing to expose the top surfaces and the bottom surfaces of the semiconductor sheets 114. The first semiconductor material of the semiconductor sheets 112 is a material that has a high etching selectivity from the etching of the semiconductor sheets 114, such as silicon germanium. The second semiconductor material of the semiconductor sheets 114 is a material suitable for both n-type and p-type devices, such as silicon.

In some embodiments, the first semiconductor material of the semiconductor sheets 112 may be made of a material such as silicon germanium (e.g., SiₓGe₁₋ₓ, where x can be in the range of 0 to 1), pure germanium, a III-V compound semiconductor, a II-VI compound semiconductor, or the like. The second semiconductor material of the semiconductor sheets 114 may be made of a material such as silicon, silicon carbide, a III-V compound semiconductor, a II-VI compound semiconductor, or the like. The first semiconductor material and the second semiconductor material may exhibit a high etching selectivity when etched, relative to each other. Each of the layers of the multi-layer stack 110 may be grown by a process such as vapor phase epitaxy (VPE) or molecular beam epitaxy (MBE), deposited by a process such as chemical vapor deposition (CVD) or atomic layer deposition (ALD), or the like. In some embodiments, the multi-layer stack 110 may have a thickness in a range from about 70 to 120 nm, such as about 70, 80, 90, 100, 110, or 120 nm. In some embodiments, each of the layers may have a thickness in a range of about 5 nm to about 40 nm. In some embodiments, some layers (e.g., the semiconductor sheets 114) are formed to be thinner than other layers (e.g., the semiconductor sheets 112).

Referring to FIGS. 5A and 5B, the substrate 100 and the multi-layer stack 110 are patterned to form semiconductor strips 116, which includes the semiconductor sheets 112 and semiconductor sheets 114, and the fins 102. The trenches T1 (or openings) are formed the substrate 100 and the multi-layer stack 110 may be patterned by any acceptable etch process, such as a reactive ion etch (RIE), neutral beam etch (NBE), the like, or a combination thereof. The etching may be anisotropic. The fins 102 and the semiconductor strips 116 may be patterned by any suitable method. For example, the fins 102 and the semiconductor strips 116 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as masks to pattern the fins 102 and the semiconductor strips 116. In some embodiments, the mask (or other layer) may remain on the semiconductor strips 116. In some embodiments, the fins 102 and the semiconductor strips 116 have substantially equal widths.

Referring to FIGS. 6A and 6B, the isolation layers 120 are formed over the substrate 100 and between adjacent fins 102. The isolation layers 120 are disposed around at least a portion of the fins 102 such that at least a portion of the semiconductor strips 116 protrude from the isolation layers 120. In some embodiments, the top surfaces of the isolation layers 120 are coplanar (within process variations) with the top surfaces of the fins 102. In some embodiments, the top surfaces of the isolation layers 120 are above or below the top surfaces of the fins 102. The isolation layers 120 separate the features of adjacent devices.

The isolation layer 120 may be formed by any suitable methods. For example, an insulation material can be formed over the substrate 100 and the semiconductor strips 116, and between adjacent fins 102. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. Although the isolation layers 120 are each illustrated as a single layer, some embodiments may utilize multiple layers. For example, in some embodiments a liner (not separately illustrated) may first be formed along surfaces of the substrate 100, the fins 102, and the semiconductor strips 116. Thereafter, a fill material, such as those previously described, may be formed over the liner.

A removal process is then applied to the insulation material to remove excess insulation material over the semiconductor strips 116. In some embodiments, a planarization process such as chemical mechanical polishing (CMP), an etch-back process, combinations thereof, or the like may be utilized. In embodiments in which a mask remains on the semiconductor strips 116, the planarization process may expose the mask or remove the mask. After the planarization process, the top surfaces of the insulation material and the mask (if present) or the semiconductor strips 116 are coplanar (within process variations). Accordingly, the top surfaces of the mask (if present) or the semiconductor strips 116 are exposed through the insulation material. In some embodiments, no mask remains on the semiconductor strips 116. The insulation material is then recessed to form the isolation layer 120. The insulation material is recessed, such as in a range from about 30 nm to about 80 nm, such that at least a portion of the semiconductor strips 116 protrude from the insulation material. Further, the top surfaces of the isolation layer 120 may have a flat surface as illustrated, a convex surface, a concave surface (such as dishing), or a combination thereof. The top surfaces of the isolation layer 120 may be formed flat, convex, and/or concave by an appropriate etch. The insulation material may be recessed using any acceptable etching process, such as one that is specific to the insulation material (e.g., selectively etches the insulation material of the isolation layer 120 at a faster rate than the materials of the fins 102 and the semiconductor strips 116). For example, an oxide removal may be performed using dilute hydrofluoric (dHF) acid.

Referring to FIGS. 7A and 7B, a dummy gate dielectric 132, a dummy gate electrode 134, and a mask 136 are sequentially formed on the fins 102 and the semiconductor strips 116. The dummy gate dielectric 132 is formed on the fins 102 and the semiconductor strips 116. The dummy gate dielectric 132 may be formed of a dielectric material such as silicon oxide, silicon nitride, a combination thereof, or the like, which may be deposited or thermally grown according to acceptable techniques. Subsequently, a dummy gate electrode 134 is formed over the dummy gate dielectric 132 to fill the trenches T1. Subsequently, a mask 136 is formed over the dummy gate electrode 134. The dummy gate electrode 134 may be deposited over the dummy gate dielectric 132 and then planarized, such as by a CMP. The mask 136 may be deposited over the dummy gate electrode 134. The dummy gate electrode 134 may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate electrode 134 may be formed of material(s) that have a high etching selectivity from the etching of insulation materials, e.g., the isolation layer 120 and/or the dummy gate dielectric 132. The mask 136 may be formed of a dielectric material such as silicon nitride, silicon oxynitride, or the like. In some embodiments, the dummy gate dielectric 132 covers the fins 102, the semiconductor strips 116, and the isolation layer 120, such that the dummy gate dielectric 132 extends over the isolation layer 120 and between the dummy gate electrode 134 and the isolation layer 120. In another embodiment, the dummy gate dielectric 132 covers only the fins 102 and the semiconductor strips 116. A removal process may be performed to remove a portion of the dummy gate dielectric 132, the dummy gate electrode 134, and the mask 136 as shown in FIG. 7B.

Referring to FIGS. 8A and 8B, the semiconductor strips 116 exposed by the mask 136 are removed. Although FIGS. 8A and 8B illustrate that the fins 102 are not removed in this stage, a portion of the fins 102 may be removed in other embodiments such that the upper surface of the fin 102 is lower than the upper surface of the isolation layer 120. In some embodiments, the semiconductor strips 116 may be removed by using an anisotropic etching process, such as an RIE, an NBE, or the like. A single etch process may be used to etch each of the semiconductor sheets 112 and semiconductor sheets 114, or multiple etch processes may be used to etch the semiconductor sheets 112 and semiconductor sheets 114.

Referring to FIGS. 9A and 9B, S/D structures 140 (see FIG. 9B) are formed over the fins 102, such that each dummy gate electrode 134 is disposed between respective adjacent pairs of the S/D structures 140. A material of the S/D structures 140 may be selected to exert stress in the respective channel regions, thereby improving performance.

Referring to FIGS. 10A and 10B, the ILD 150 is deposited over the S/D structures 140. The ILD 150 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. Subsequently, a removal process is performed to align the top surfaces of the ILD 150 with the top surfaces of the mask 136. In some embodiments, a planarization process such as CMP, an etch-back process, combinations thereof, or the like may be utilized.

Referring to FIGS. 11A and 11B, the mask 136 and the dummy gate dielectric 132 and the dummy gate electrode 134 are removed by an etching process(es) to form trenches T2 (or openings). In some embodiments, the dummy gate dielectric 132 and the dummy gate electrode 134 are removed by an anisotropic dry etch process. For example, the etching process may include a dry etch process using reaction gas(es) that selectively etch the dummy gate dielectric 132 and the dummy gate electrode 134 at a faster rate than the ILD 150. The dummy gate dielectric 132 is then removed. In some embodiments, the remaining portion of the semiconductor sheets 112 are removed. The remaining portions of the semiconductor sheets 112 can be removed by any acceptable etching process that selectively etches the material of the semiconductor sheets 112 at a faster rate than the material of the semiconductor sheets 224. Each of the trenches T2 exposes portions of the channel regions. Portions of the semiconductor sheets 114 which act as the channel regions are disposed between adjacent pairs of the S/D structures 140. Portions of the fins 102 are exposed by the trenches T2.

Referring to FIGS. 12A and 12B, gate structures (e.g., the gate structures 160a and 160b) are formed within the trenches T2 to wrap around the semiconductor sheets 114 (see FIG. 12A). A gate dielectric layer 162 is formed in the trenches T2. The gate dielectric layer 162 is disposed on the sidewalls and/or the top surfaces of the fins 102 as well as on the top surfaces, the sidewalls, and the bottom surfaces of the semiconductor sheets 114. The gate dielectric layer 162 may include an oxide such as silicon oxide or a metal oxide, a silicate such as a metal silicate, combinations thereof, multi-layers thereof, or the like. The gate electrode layers 164 are formed on the gate dielectric layer 162. In some embodiments, a removal process can be performed to remove the excess portions of the materials of the gate dielectric layer 162 and the gate electrode layer 164, which extend beyond the top surfaces of the ILD 150. In some embodiments, a planarization process such as CMP, an etch-back process, combinations thereof, or the like may be utilized. The gate dielectric layer 162 and the gate electrode layer 164 are layers for replacement gates, and each wrap around all (e.g., four) sides of the semiconductor sheets 114.

Referring to FIGS. 13A and 13B, a removal process is performed to form trenches T3 (or openings). The trenches T3 are configured to define the pattern of gate-cut structures (e.g., the gate-cut structures 170a and 170b as shown in FIG. 1). In some embodiments, a portion of the gate electrode layer 164, the isolation layer 120, and the fins 102 are removed. As a result, the lateral surface of the gate electrode layer 164 is exposed, the lateral surface of the isolation layer 120 is exposed, and an upper surface of the substrate 100 is exposed. In some embodiments, a wet etching process may be performed. A hydroxide containing solution (e.g., ammonium hydroxide), deionized water, and/or other suitable etchant solutions may be utilized to perform the wet etching process. In some embodiments, the trenches T3 have different lengths for accommodating gate-cut structures of different lengths.

Referring to FIGS. 14A and 14B, the leakage barrier layers 172 are formed within the trenches T3. The leakage barrier layers 172 are formed on the lateral surface and the upper surface of the gate electrode layer 164, on the lateral surface of the isolation layer 120, and on the upper surface of the substrate 100. In some embodiments, the leakage barrier layer 172 is formed by ALD, CVD, PECVD, or other suitable processes.

In some embodiments, the precursor for forming the leakage barrier layer 172 includes metal halides or other metal derivatives. For example, the precursor for forming the leakage barrier layer 172 may include trimethylaluminum, triisobutylaluminum, aluminum chloride, dimethylethylaluminum, diisobutylaluminum, aluminum acetylacetonate, hafnium tetrachloride, hafnium tetracthoxide, hafnium tetra(2,2,6,6-tetramethyl-3,5-heptanedionate), hafnium diisopropoxide bis(dimethylamide)diisopropoxide, hafnium tetramethylamide, zirconium tetrachloride, zirconium tetraethoxide, zirconium tetra(2,2,6,6-tetramethyl-3,5-heptanedionate), zirconium diisopropoxide bis(dimethylamide)diisopropoxide, zirconium tetramethylamide, titanium tetrachloride, titanium tetraisopropoxide, titanium tetra(2,2,6,6-tetramethyl-3,5-heptanedionate), titanium bis(ethylacetoacetato)(isopropoxide), titanium tetramethylamide, gadolinium acetylacetonate, gadolinium triisopropoxide, gadolinium tetra(2,2,6,6-tetramethyl-3,5-heptanedionate), gadolinium tris(dimethylamide)triethylamine, gadolinium cyclopentadienyl, lanthanum acetylacetonate, lanthanum triisopropoxide, lanthanum tetra(2,2,6,6-tetramethyl-3,5-heptanedionate), lanthanum tris(dimethylamide)triethylamine, lanthanum cyclopentadienyl, yttrium acetylacetonate, yttrium triisopropoxide, yttrium tetra(2,2,6,6-tetramethyl-3,5-heptanedionate), yttrium tris(dimethylamide)triethylamine, yttrium cyclopentadienyl, lutetium acetylacetonate, lutetium triisopropoxide, lutetium tetra(2,2,6,6-tetramethyl-3,5-heptanedionate), lutetium tris(dimethylamide)triethylamine, lutetium cyclopentadienyl, scandium oxide, Scandium acetylacetonate, scandium triisopropoxide, scandium tetra(2,2,6,6-tetramethyl-3,5-heptanedionate), scandium tris(dimethylamide)triethylamine, scandium cyclopentadienyl, dysprosium oxide, dysprosium acetylacetonate, dysprosium triisopropoxide, dysprosium tetra(2,2,6,6-tetramethyl-3,5-heptanedionate), dysprosium tris(dimethylamide)triethylamine, dysprosium cyclopentadienyl, or other suitable precursors. In some embodiments, O₂, H₂O, O₃, N₂, NH₃, N₂H₄, Ar, He, H₂, Ne, Kr, Xe, may be used as reactant gases and/or diluted gases. In some embodiments, during the formation of the leakage barrier layer 172, oxidation of the gate electrode layer 164 is avoided due to the relatively low concentration of oxygen-containing gases (e.g., O₂, H₂O, and/or O₃). In some embodiments, the precursors for forming aluminum oxide includes trimethylaluminum and tert-Butanol, which can be free of oxidation of the gate electrode layer 164.

Referring to FIGS. 15A and 15B, the dielectric layer 174 is formed on the leakage barrier layer 172 and fills the trenches T3. In some embodiments, the dielectric layer 174 is formed by ALD, CVD, FCVD, or other suitable processes. In some embodiments, the thickness (e.g., a length along the Y direction or Z direction) of the dielectric layer 174 is greater than the thickness of the leakage barrier layer 172. The air gap 176 can be defined within the dielectric layer 174. In some embodiments, the concentration of oxygen-containing gases (e.g., O₂, H₂O, and/or O₃) at the stage for forming the dielectric layer 174 is greater than that for forming the leakage barrier layer 172.

Referring to FIGS. 16A and 16B, a planarization process such as CMP, an etch-back process, combinations thereof, or the like may be utilized to remove excesses portions, which extend over the ILD 150 and the gate electrode layer 164, of the leakage barrier layer 172 and the dielectric layer 174. As a result, a semiconductor device (e.g., the semiconductor device 10) is produced.

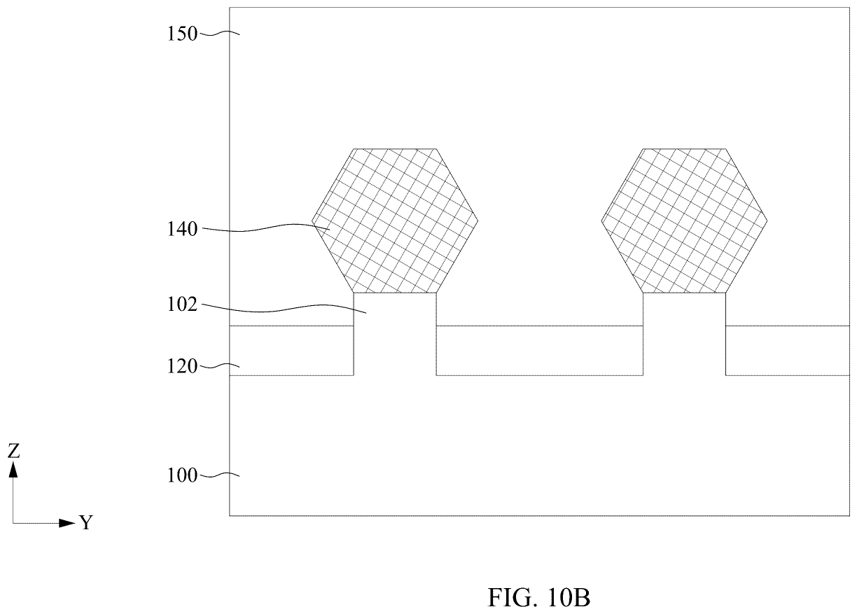

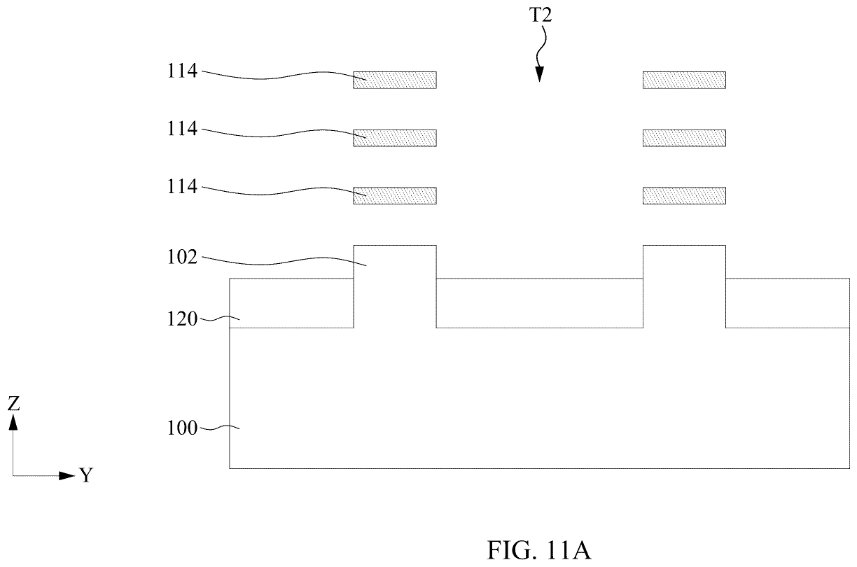

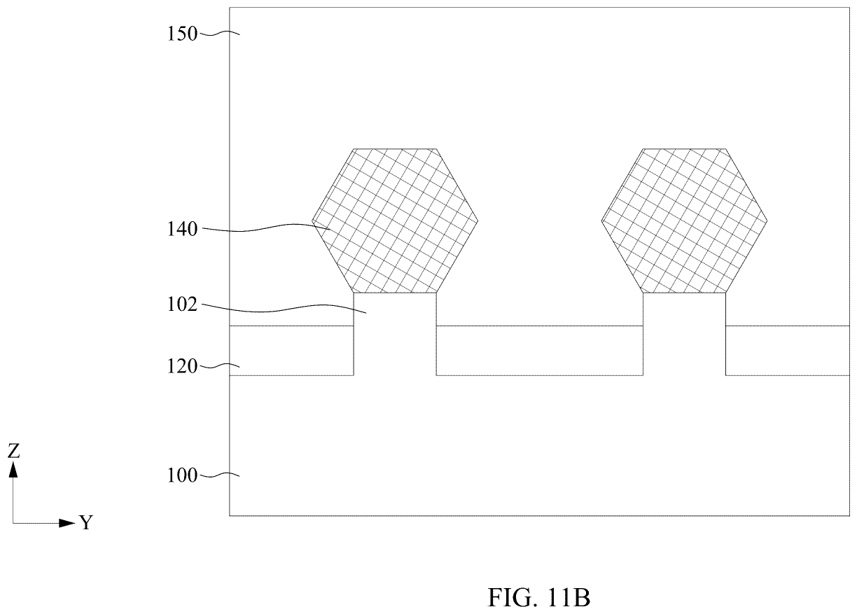

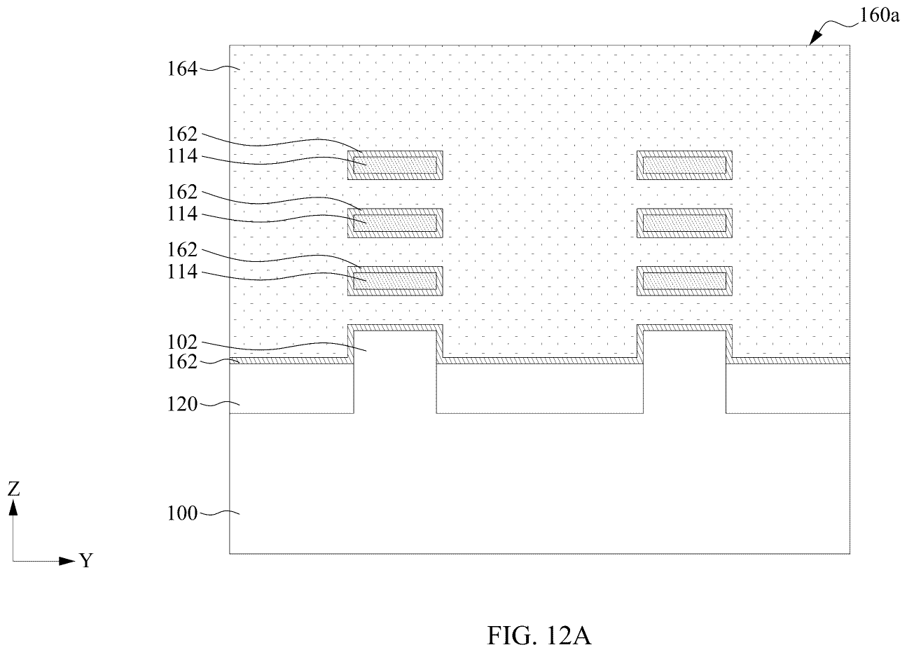

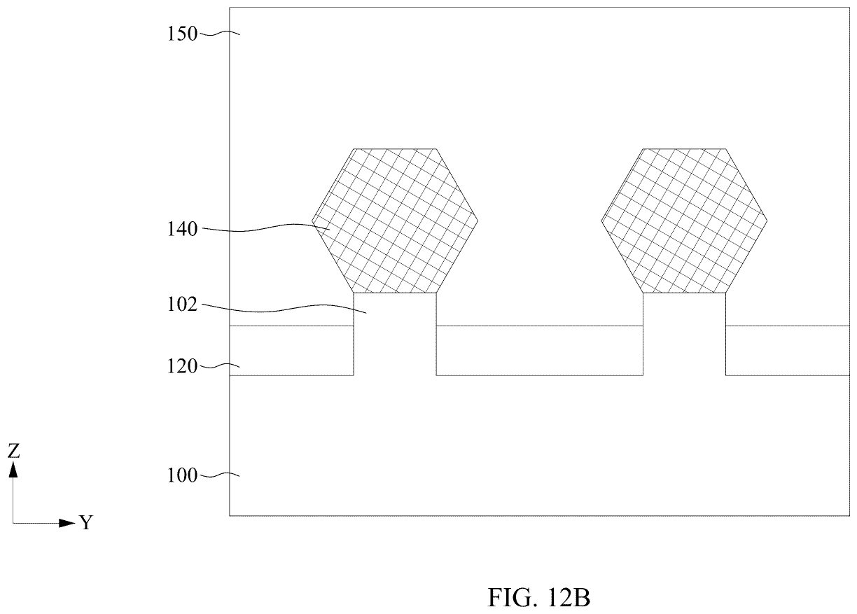

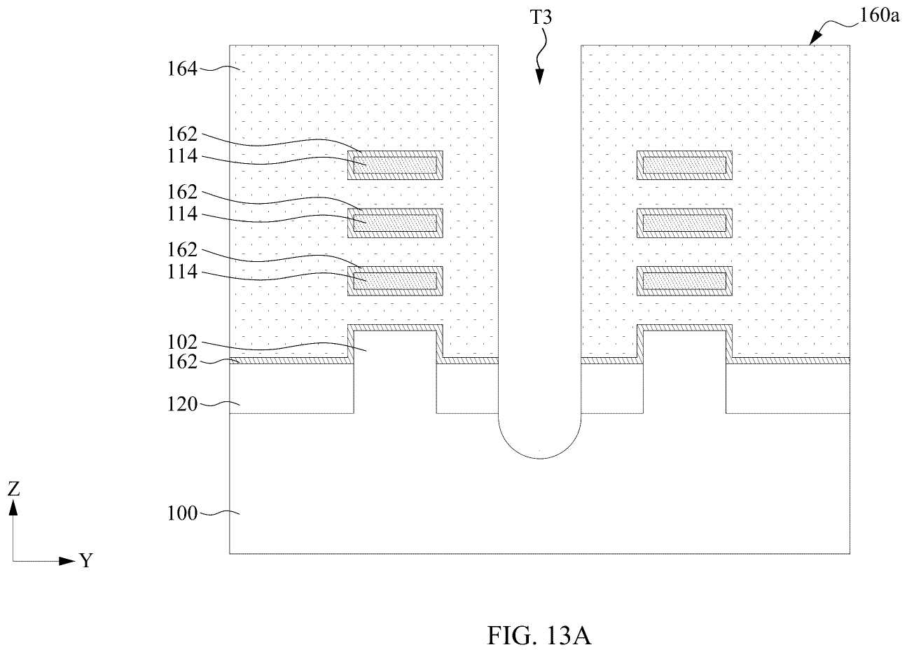

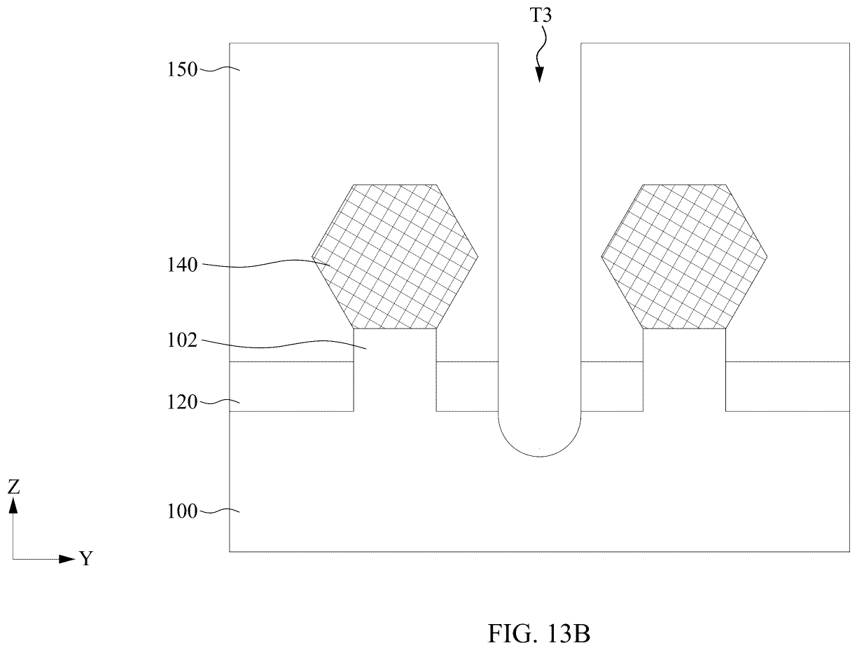

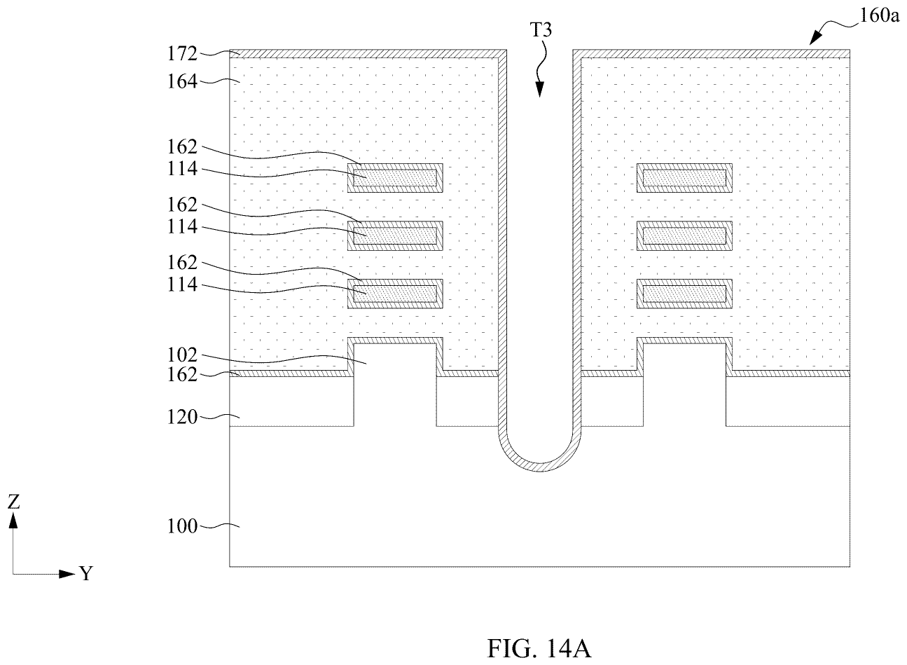

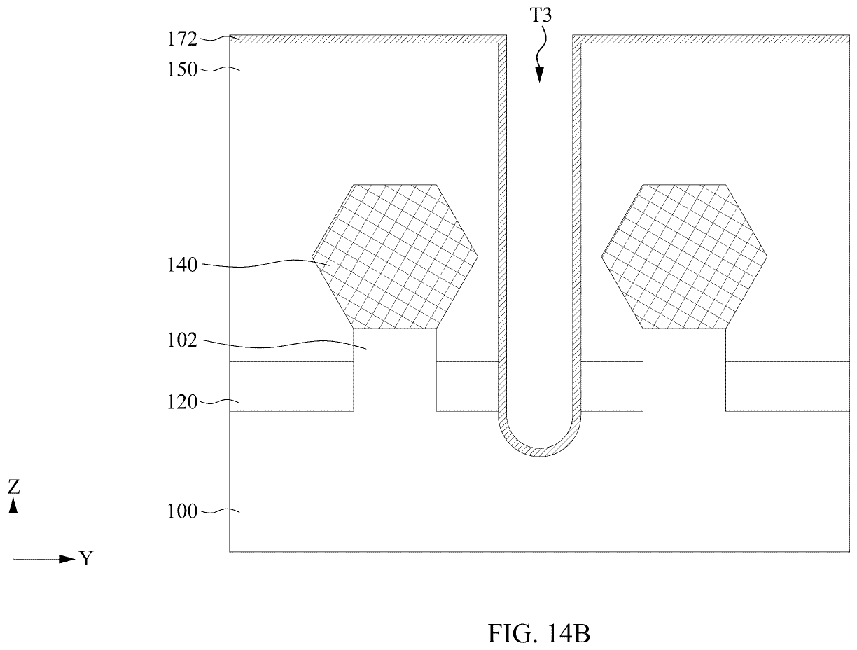

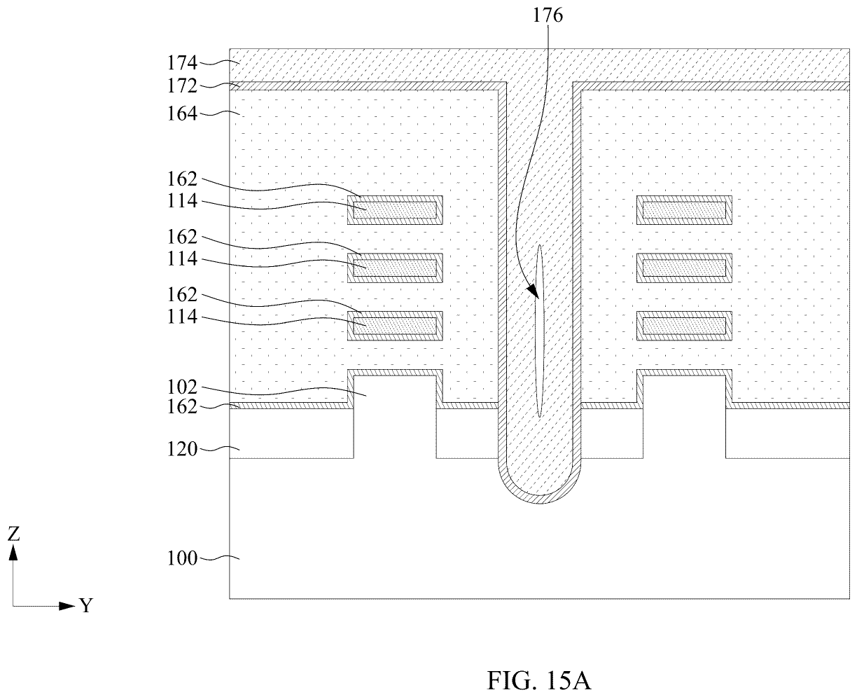

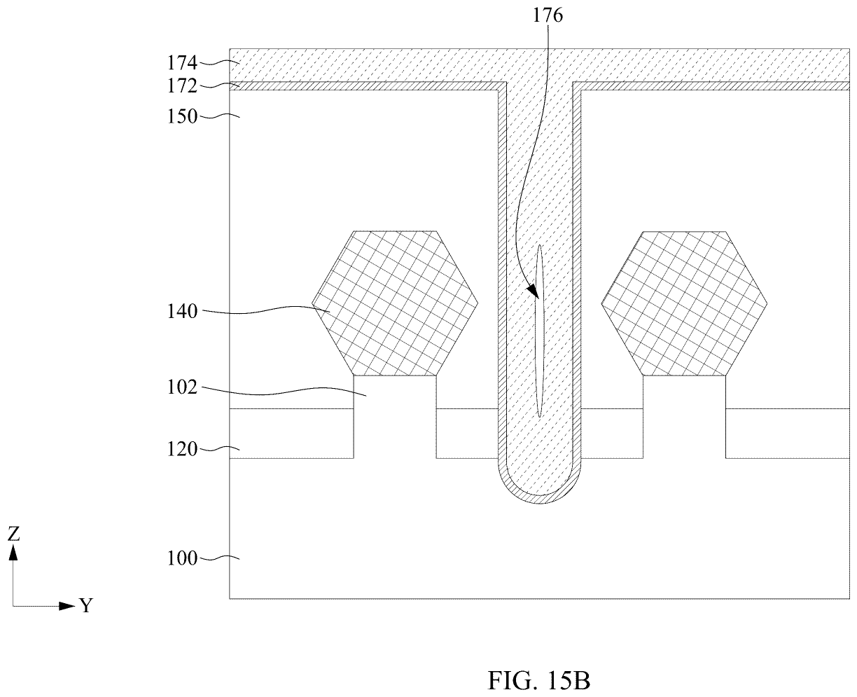

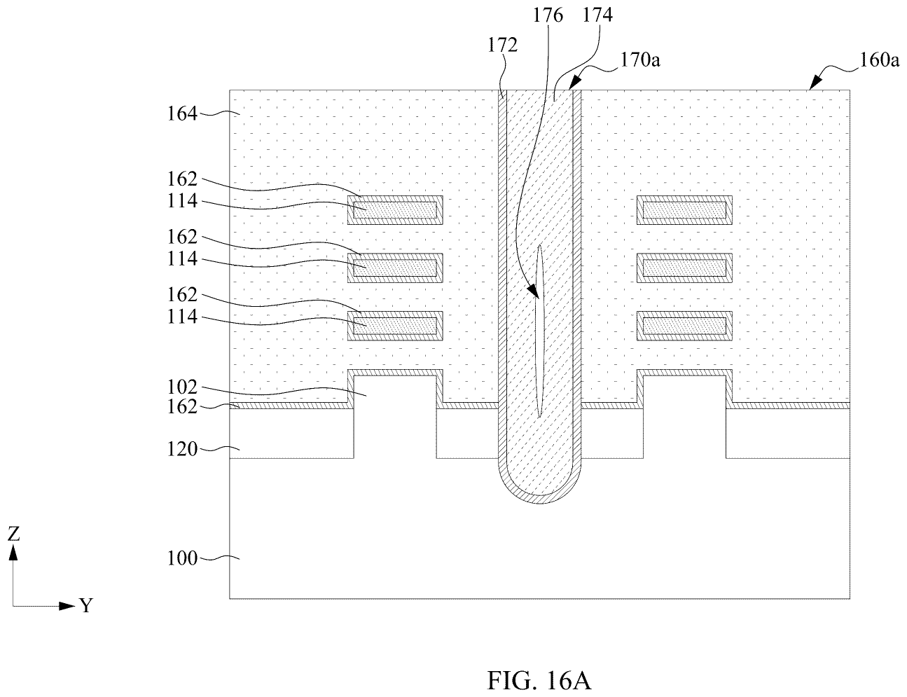

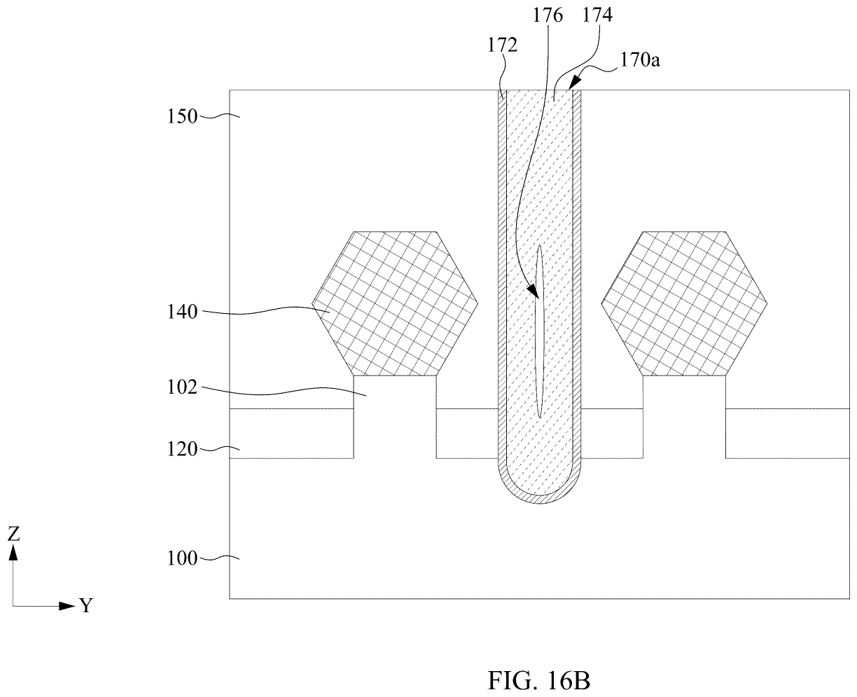

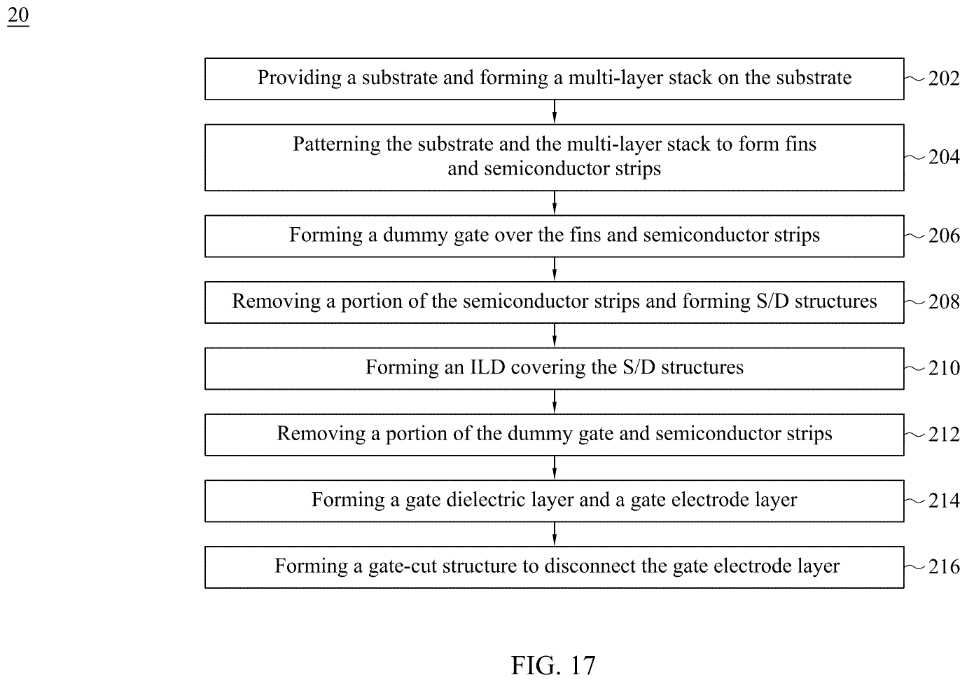

FIG. 17 is a flowchart of a method 20 for manufacturing a semiconductor device according to various aspects of the present disclosure.

The method 20 begins with operation 202 in which a substrate is provided. A multi-layer stack is formed on the substrate.

The method 20 continues with operation 204 in which the substrate and the multi-layer stack are patterned to form fins and semiconductor strips over the fins.

The method 20 continues with operation 206 in which a dummy gate is formed to cover the fins and the semiconductor strips.

The method 20 continues with operation 208 in which a portion of the semiconductor strips is removed and S/D structures are formed over the fins.

The method 20 continues with operation 210 in which an ILD is formed to cover the S/D structures.

The method 20 continues with operation 212 in which a portion of the dummy gate and a portion of the semiconductor strips are removed to expose nanostructures.

The method 20 continues with operation 214 in which a gate dielectric layer and a gate electrode layer are formed to wrap the nanostructures.

The method 20 continues with operation 216 in which the gate electrode layer is patterned to form an opening, and a gate-cut structure is formed within the opening to disconnect the gate electrode layer. Forming the gate-cut structure includes forming a negative fixed charge material (e.g., metal nitride, metal oxide, or other suitable materials) and an isolation layer, which has a relatively low dielectric constant, on the negative fixed charge material.

The method 20 is merely an example, and is not intended to limit the present disclosure beyond what is explicitly recited in the claims. Additional operations can be provided before, during, and after the method 20, and some operations described can be replaced, eliminated, or reordered for additional embodiments of the method.

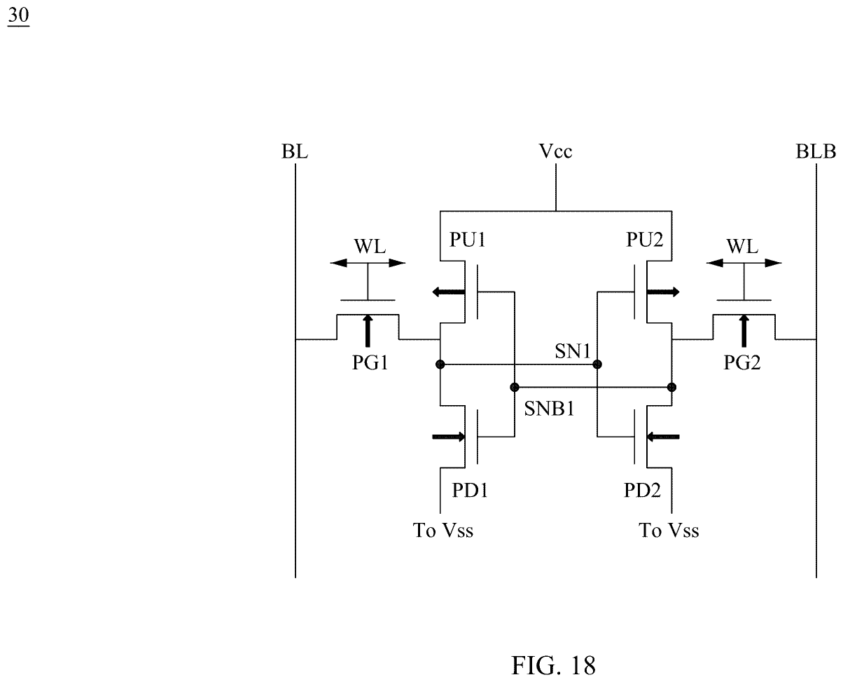

FIG. 18 illustrates an example circuit schematic for an SRAM cell (e.g., 1-bit SRAM cell) 30. The SRAM cell 30 includes pull-up transistors PU1, PU2; pull-down transistors PD1, PD2; and pass-gate transistors PG1, PG2. As show in the circuit diagram, transistors PU1 and PU2 are p-type transistors, and transistors PG1, PG2, PD1, and PD2 are n-type transistors. Since the SRAM cell 30 includes six transistors in the illustrated embodiment, it may also be referred to as a 6T SRAM cell.

The drains of pull-up transistor PU1 and pull-down transistor PD1 are coupled together, and the drains of pull-up transistor PU2 and pull-down transistor PD2 are coupled together. Transistors PU1 and PD1 are cross-coupled with transistors PU2 and PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a complementary first storage node SNB1. Sources of the pull-up transistors PU1 and PU2 are coupled to power voltage Vcc (also referred to as Vdd), and the sources of the pull-down transistors PD1 and PD2 are coupled to a voltage Vss, which may be an electrical ground in some embodiments.

The first storage node SN1 of the first data latch is coupled to bit line BL through pass-gate transistor PG1, and the complementary first storage node SNB1 is coupled to complementary bit line BLB through pass-gate transistor PG2. The first storage node N1 and the complementary first storage node SNB1 are complementary nodes that are often at opposite logic levels (logic high or logic low). Gates of pass-gate transistors PG1 and PG2 are coupled to a word line WL.

Again, according to various aspects of the present disclosure, each of the transistors PU1, PU2, PD1, PD2, PG1, and PG2 may be implemented with a dual-layer or a tri-layer gate dielectric structure discussed above. Doing so will improve the gate leakage issues and also the performance of the SRAM device, for example with respect to speed and power dissipation. It is also understood that although SRAM devices are used as a non-limiting example for IC applications that could implement the various aspects of the present disclosure, other types of IC applications may also implement the various aspects of the present disclosure. For example, the multi-layer gate dielectric scheme herein may be applied to periphery logic circuit devices in an SRAM device (such as row decoder, column decoder, read/write circuitry), or other circuit devices such as ring oscillators, radio frequency (RF) devices, amplifiers, mixers, analog-to-digital converters (ADCs), digital-to-analog converters (DACs), and the like.

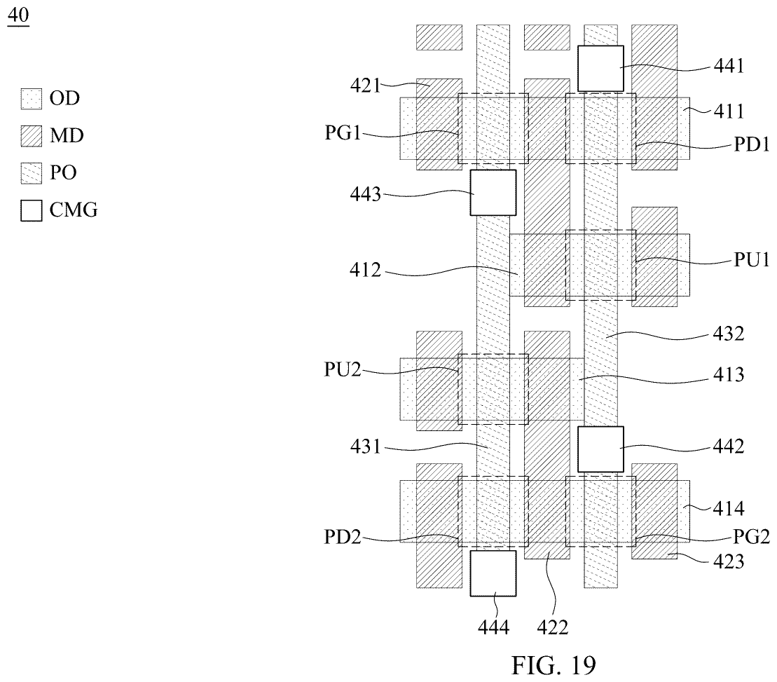

Referring to FIG. 19, the SRAM cell 30 may be implemented using a layout 40. The layout 40 includes active region structures 411, 412, 413, and 414. In some embodiments, the active region structures 411 and 414 have a first conductive type, and the active region structures 412 and 413 have a second conductive type. Non-limiting examples of the active region structures 411, 412, 413, and 414 include fin field-effect transistor (FinFETs), nano-sheet transistors, and nano-wire transistors. In some embodiments, the active region structures 411, 412, 413, and 414 can be referred to as an oxide definition region (also referred to as “OD”).

The layout 40 includes contacts 421, 422, and 423. The contacts 421, 422, and 423 intersect the active region structures 411, 412, 413, and 414 at the source/drain (S/D) regions of transistors. In some embodiments, the contacts 421, 422, and 423 can be referred to as metal diffusion (MD) conductive features of a semiconductor device. In some embodiments, each of the contacts 421, 422, and 423 corresponds to a source/drain contact of a semiconductor device.

The layout 40 includes gate structures 431 and 432. The gate structures 431 and 432 intersect the active region structures 411, 412, 413, and 414 at the channel regions of transistors. In some embodiments, the gate structures 431 and 432 can be referred to as poly (PO) of a semiconductor device.

The layout 40 includes gate-cut structures 441, 442, 443, and 444. In some embodiments, the gate-cut structures 441, 442, 443, and 444 is configured to disconnect the gate structure 431 or 432. For example, the gate-cut structures 441 and 442 are configured to disconnect the gate structure 432; the gate-cut structures 443 and 444 are configured to disconnect the gate structure 431. The gate-cut structures 441, 442, 443, and 444 can also be referred to as “CMG.”

As shown in FIG. 19, the active region structure 411, the contacts 421 and 422, as well as the gate structure 431 can exhibit or define the transistor PG1 as shown in FIG. 18. The active region structure 411, the contacts 422 and 423, as well as the gate structure 432 can exhibit or define the transistor PD1 as shown in FIG. 18. The active region structure 412, the contacts 422 and 423, as well as the gate structure 432 can exhibit or define the transistor PU1 as shown in FIG. 18. The active region structure 413, the contacts 421 and 422, as well as the gate structure 431 can exhibit or define the transistor PU2 as shown in FIG. 18. The active region structure 414, the contacts 421 and 422, as well as the gate structure 431 can exhibit or define the transistor PD2 as shown in FIG. 18. The active region structure 414, the contacts 422 and 423, as well as the gate structure 432 can exhibit or define the transistor PD2 as shown in FIG. 18.

In some cases, the gate-cut structure 441 and/or 442 has a dielectric material that generates positive fixed charges adjacent to an interface between the dielectric material and a substrate (e.g., silicon substrate). In this condition, the positive fixed charges may induce embedded floating voltage at transistor PU1 and body leakage at transistor PD1. In the embodiments of the present disclosure, the gate-cut structure 170a (or 170b), which has a barrier layer generating negative fixed charges adjacent to an interface between the substrate and the barrier layer, can be applicable to at least the gate-cut structure 441 and/or 442 to address the aforementioned issues. In some embodiments, the gate-cut structure 170a (or 170b) can be applicable to the gate-cut structure 443 and/or 444. In some other embodiments, the gate-cut structure 443 and/or 444 has a dielectric material that generates positive fixed charges adjacent to an interface between the dielectric material and the substrate. For example, the leakage barrier layer 172 of the gate-cut structure 443 and/or 444 can be replaced by silicon nitride or other materials that generates positive fixed charges adjacent to an interface between the dielectric material and the substrate.

In some embodiments, each of the gate-cut structures 441, 442, 443, and 444 include the leakage barrier layer 172 (e.g., aluminum oxide) as a liner and the dielectric layer 174. In some embodiments, the gate-cut structures 441 and 442 include the leakage barrier layer 172 (e.g., aluminum oxide) and the dielectric layer 174, while the gate-cut structures 443 and 443 include silicon nitride as a liner and the dielectric layer 174 over silicon nitride.

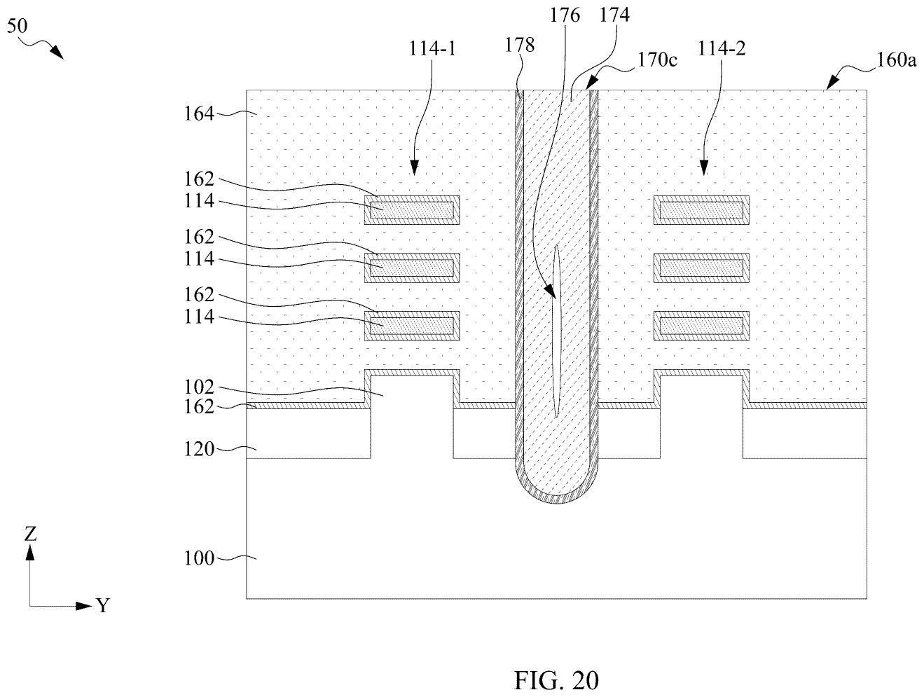

FIG. 20 is a cross-sectional view of a semiconductor device 50 in accordance with some embodiments. The semiconductor device 50 has a structure similar to that of the semiconductor device 10, with differences outlined below.

The semiconductor device 50 has a gate-cut structure 170c. The gate-cut structure 170c has a liner 178. In some embodiments, the liner 178 is configured to generate positive fixed charges adjacent to the interface between the substrate 100 and the liner 178. In some embodiments, the liner 178 includes silicon nitride or other suitable materials that generate positive fixed charges adjacent to the interface between the substrate 100 and the liner 178. In some embodiments, the gate-cut structure 170c can be applicable to the gate-cut structures 443 and 444 as shown in FIG. 19.

Some embodiments of the present disclosure provide a semiconductor device. The semiconductor device includes a substrate, a first set of nanostructures and a second set of nanostructures on the substrate, a first gate electrode wrapping the first set of nanostructures and the second set of nanostructures, and a gate-cut structure between the first set of nanostructures and the second set of nanostructures. The gate-cut structure includes a barrier layer adjacent to the first gate electrode and a dielectric layer spaced apart from the first gate electrode by the barrier layer.

Some embodiments of the present disclosure provide a semiconductor device. The semiconductor device includes a substrate, a gate electrode on the substrate, and a first barrier layer penetrating the gate electrode and a portion of the substrate. The first barrier layer is configured to generate negative fixed charges adjacent to an interface between the substrate and the first barrier layer.

Some embodiments of the present disclosure provide a method of manufacturing a semiconductor device. The method includes providing a substrate. The method also includes forming a gate electrode over the substrate. The method further includes patterning the gate electrode to form an opening. In addition, the method includes forming a barrier layer within the opening and forming a dielectric layer to fill the opening.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first set of nanostructures and a second set of nanostructures on the substrate;
a first gate electrode wrapping the first set of nanostructures and the second set of nanostructures; and
a gate-cut structure between the first set of nanostructures and the second set of nanostructures, comprising:
a barrier layer adjacent to the first gate electrode; and
a dielectric layer spaced apart from the first gate electrode by the barrier layer.

2. The semiconductor device of claim 1, wherein the barrier layer comprises aluminum oxide.

3. The semiconductor device of claim 1, wherein the barrier layer is in contact with the substrate.

4. The semiconductor device of claim 3, wherein the substrate comprises a first well region with a first conductive type and a second well region with a second conductive type different from the first conductive type, and the barrier layer is disposed on the first well region and the second well region.

5. The semiconductor device of claim 1, wherein the gate-cut structure comprises an air gap within the dielectric layer.

6. The semiconductor device of claim 1, wherein a dielectric constant of the dielectric layer is less than that of the barrier layer.

7. The semiconductor device of claim 1, further comprising:
a second gate electrode parallel to the first gate electrode,
wherein the gate-cut structure penetrates the first gate electrode and the second gate electrode.

8. The semiconductor device of claim 7, wherein the gate-cut structure extends between the first gate electrode and the second gate electrode.

9. The semiconductor device of claim 1, wherein the barrier layer is configured to generate negative fixed charges adjacent to an interface between the substrate and the barrier layer.

10. A semiconductor device, comprising:
a substrate;
a gate electrode on the substrate; and
a first barrier layer penetrating the gate electrode and a portion of the substrate, wherein the first barrier layer is configured to generate negative fixed charges adjacent to an interface between the substrate and the first barrier layer.

11. The semiconductor device of claim 10, further comprising:
a dielectric layer surrounded by the first barrier layer, wherein a dielectric constant of the dielectric layer is less than that of the first barrier layer.

12. The semiconductor device of claim 10, wherein the first barrier layer comprises metal oxide, metal nitride, or a combination thereof.

13. The semiconductor device of claim 10, further comprising:
a second barrier layer, wherein a first length of the first barrier layer is different from a second length of the second barrier layer along a direction that is substantially orthogonal to an extending direction of the gate electrode.

14. The semiconductor device of claim 10, further comprising:
a first epitaxial structure and a second epitaxial structure disposed on the substrate, wherein the first barrier layer is disposed between the first epitaxial structure and the second epitaxial structure.

15. The semiconductor device of claim 14, further comprising:
an interlayer dielectric (ILD) covering the first epitaxial structure and the second epitaxial structure,
wherein the first barrier layer penetrates the ILD.

16. A method of manufacturing a semiconductor device, comprising:
providing a substrate;
forming a gate electrode over the substrate;
patterning the gate electrode to form an opening;
forming a barrier layer within the opening; and
forming a dielectric layer to fill the opening.

17. The method of claim 16, wherein the barrier layer comprises metal oxide, metal nitride, or a combination thereof.

18. The method of claim 16, further comprising:
forming a dummy gate;
removing a first portion of the dummy gate to form a first trench;
forming an epitaxial structure within the first trench;
forming an interlayer dielectric to fill the first trench; and
removing a second portion of the dummy gate to form a second trench,
wherein the gate electrode is formed within the second trench.

19. The method of claim 16, further comprising:
forming a first set of nanostructures and a second set of nanostructures on the substrate; and
forming a gate dielectric wrapping the first set of nanostructures and the second set of nanostructures,
wherein the opening is formed between the first set of nanostructures and the second set of nanostructures.

20. The method of claim 16, wherein the barrier layer is configured to generate negative fixed charges adjacent to an interface between the substrate and the barrier layer.
